(19) United States
(12) Patent Application Publication
(10) Pub. No.: US 2009/0184774 A1
(43) Pub. Date: Jul. 23, 2009

(54) TRANSISTOR VOLTAGE-CONTROLLED OSCILLATOR

(75) Inventors: Ping-Yuan Deng, Taipei (TW); Jean-Fu Kiang, Taipei (TW)

Correspondence Address: LAW OFFICES OF MIKIO ISHIMARU, 333 W. EL CAMINO REAL, SUITE 330, SUNNYVALE, CA, 94087, US

(73) Assignee: NATIONAL TAIWAN UNIVERSITY, Taipei (TW)

(21) Appl. No.: 12/165,296

(22) Filed: Jun. 30, 2008

(30) Foreign Application Priority Data
Jan. 17, 2008 (TW) 097101742

(51) Int. Cl. H03B 5/24

(52) U.S. Cl. 331/117 FE

(57) ABSTRACT

A transistor voltage-controlled oscillator includes a cross-coupled LC-tank transistor voltage-controlled oscillating circuit composed of two transistors, a capacitor set, and a first transformer inductor having a first inductor coil and a second inductor coil coupled to the first inductor coil; and a second transformer inductor having a third inductor coil and a fourth inductor coil coupled to the third inductor coil. The first transformer inductor and the second transformer inductor are both used as a coupling inductor for the cross-coupled LC-tank transistor voltage-controlled oscillating circuit. As a result, the inductor area of the transistor voltage-controlled oscillator is greatly reduced and the parasitic capacitance between the inductors and the silicon substrate is reduced accordingly such that the power consumption is greatly reduced and the quality factor of the inductor is increased.

### BACKGROUND OF THE INVENTION

1. Field of the Invention

The invention relates to a voltage-controlled oscillator, and more specifically, to a transistor voltage-controlled oscillator.

2. Prior Art

Design of a voltage-controlled oscillator has always been the design focus in the field of wireless communications circuit design. In the wireless RF circuit, the voltage-controlled oscillator plays an extremely crucial role in the modulation/demodulation process of the RF front-end circuit. Also, as a voltage-controlled oscillator often comprises quite a number of capacitors, inductors, transistors and other active or passive components, therefore the voltage-controlled oscillating circuit has always been the part in the wireless RF circuit that takes up the largest area and consumes the most power.

FIG. 1 depicts a conventional cross-coupled LC-tank transistor voltage-controlled oscillator. The voltage-controlled oscillator consists of a pair of cross-coupled transistors, two pairs of inductor L and one pair of capacitor C. The circuit operation is based on an external voltage source V_{DD} to control the switching of the gate terminals of the cross-coupled transistors. The external voltage source provides the transistor voltage-controlled oscillating circuit with the required working voltage. Then the oscillating frequency of the working signal is determined by the inductor and the variable capacitor of the LC-tank of the transistor voltage-controlled oscillating circuit.

Firstly, power consumption of the voltage-controlled oscillating circuit is discussed. Inductors and other passive components included in the circuit shall not consume any signal power under ideal condition, and parasitic resistance does not exist in an ideal equivalent circuit, therefore an ideal inductor shall store and release the energy of the signal without loss in the form of electromagnetic field. Only under practical circumstances, when passive components are integrated into silicon chips in particular, can the effect of parasitic resistance appear significantly in passive components and the silicon substrate.

The parasitic capacitance refers to a very small, undesired capacitance existing between conducting wires and the silicon substrate of an integrated circuit. Under the condition of low oscillating frequency, the effect of parasitic capacitance is not obvious and therefore can be ignored. As the oscillating frequency is increased, the effect of parasitic capacitance will gradually become more apparent, wherein the frequency suppression effect shall be carefully taken into consideration.

In order to describe the effect of parasitic resistance on the power consumed by passive components, a quality factor Q, representing the degree of which the signal power is consumed by the components, is defined. The quality factor Q is defined as the ratio of the maximum stored energy in an ideal inductor to the energy consumed by the parasitic resistance during every signal cycle. In other words, the greater is the Q-factor, the lesser the impact of the parasitic resistance on the passive component. The Q-factor of an ideal component shall approach infinity.

When passive components are integrated into a silicon chip, the parasitic capacitance often appears at the border where conducting wires and silicon substrate are connected. As the area of the contact between the conducting wire and the substrate is increased, the parasitic capacitance effect shall also become more obvious. As shown in FIG. 1, the oscillator also has four inductors in addition to capacitors. The four inductors take up most of the circuit chip area, therefore the parasitic capacitance effect between the inductors and the silicon substrate shall be further considered.

As described above, even though integrating chip inductor on the silicon substrate leads to substrate parasitic resistance that attenuates the signal, thereby causing the problem of low Q-factor, most researches still focus on integrating inductors into the chip. The primary reason is that if passive components such as inductor can be integrated into a single chip, then the external component count can be significantly reduced, thus lowering the cost and the die size.

Hence, it has become an urgent issue to designers in the voltage-controlled oscillator to devise a way to design a voltage-controlled oscillating circuit that not only enables integration of multiple inductors into a single chip such that the die size is greatly reduced but also lowers the energy consumed by the parasitic resistance present in the silicon substrate during the process of integrating inductors into a silicon chip, thereby avoiding the problem of low Q-factor.

### SUMMARY OF THE INVENTION

In view of the above disadvantages of the conventional technique, it is a primary objective of the present invention to provide a transistor voltage-controlled oscillator that allows an integration of multiple inductors into a single chip, thereby reducing the die size significantly.

Another objective of the invention is to provide a transistor voltage-controlled oscillator that allows integrating inductors into the silicon chip during the chip process, thereby lowering the power consumption due to parasitic resistance of the silicon substrate, such that the problem of low Q-factor is avoided.

In order to achieve the aforementioned objectives, the present invention provides a transistor voltage-controlled oscillator. The transistor voltage-controlled oscillator in the present invention includes at least: a cross-coupled LC-tank transistor voltage-controlled oscillating circuit having a first transistor with a first gate terminal, a first source terminal and a first drain terminal, and a second transistor with a second gate terminal, a second source terminal and a second drain terminal; a first transformer inductor used as a coupling inductor in the cross-coupled LC-tank transistor voltage-controlled oscillating circuit includes a first induction coil and a second induction coil, further the first induction coil is connected to the first drain terminal, and the second induction coil is connected to the first source terminal; and a second transformer inductor used as another coupling inductor in the cross-coupled LC-tank transistor voltage-controlled oscillating circuit includes a third induction coil and a fourth induction coil, further the third induction coil is connected to the second drain terminal and the fourth induction coil is connected to the second source terminal.

In comparison to the conventional technique, the transistor voltage-controlled oscillator in the present invention includes a first transformer inductor having a first induction coil and a second induction coil, further the first induction coil is connected to the first drain terminal, the second induction coil is connected to the first source terminal; and a second transformer inductor including a third induction coil and a fourth induction coil, further the third induction coil is connected to the second drain terminal, the fourth induction coil is connected to the second source terminal. The two above-mentioned transformer inductors are used as the coupling inductors in the cross-coupled LC-tank transistor voltage-controlled oscillating circuit thus, the area taken up by the inductor of the transistor voltage-controlled oscillator can be greatly reduced. As reducing the inductor area lowers the parasitic capacitance present between the inductor and the silicon substrate, a significant reduction in the power consumption can be achieved, which in turn increases the Q-factor of the inductor.

### BRIEF DESCRIPTION OF THE DRAWINGS

FIG. 1 is a block diagram of a conventional cross-coupled LC-tank transistor voltage-controlled oscillator;

FIG. 2 is a circuit diagram of a transistor voltage-controlled oscillator in the present invention;

FIG. 3a is a block diagram of a planar transformer of a transistor voltage-controlled oscillator in the present invention;

FIG. 3b is an equivalent circuit diagram of a planar transformer of a transistor voltage-controlled oscillator in the present invention;

FIG. 4 is a circuit diagram of a transistor voltage-controlled oscillator in a second embodiment; and

FIG. 5 is a circuit diagram of a transistor voltage-controlled oscillator in a third embodiment.

### DETAILED DESCRIPTION OF PREFERRED EMBODIMENTS

The following illustrative embodiments are provided to illustrate the disclosure of the present invention, these and other advantages and effects can be apparently understood by those in the art after reading the disclosure of this specification. The present invention can also be performed or applied by other different embodiments. The details of the specification may be on the basis of different points and applications, and numerous modifications and variations can be devised without departing from the spirit of the present invention.

The following embodiments further illustrate the points of the present invention in detail, however the invention is not limited to any points.

### First Embodiment

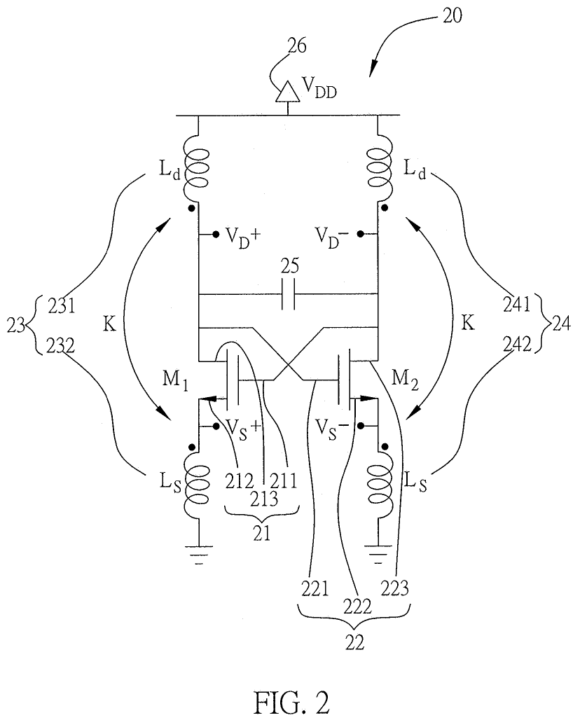

Referring to FIG. 2, a circuit diagram of a transistor voltage-controlled oscillator in the present invention is illustrated. The oscillator is a cross-coupled LC-tank transistor voltage-controlled oscillating circuit 20 having a first transistor 21 with a first gate terminal 211, a first source terminal 212 and a first drain terminal 213; a second transistor 22 with a second gate terminal 221, a second source terminal 222 and a second drain terminal 223, wherein the first gate terminal 211 is coupled to the second drain terminal 223 and the second gate terminal 221 is coupled to the first drain terminal 213, forming a cross-coupled transistor structure; a first transformer inductor 23, wherein the inductor is a coupling inductor in the cross-coupled LC-tank voltage-controlled oscillating circuit 20, and the first transformer inductor 23 includes a first induction coil 231 and a second induction coil 232, further the first induction coil 231 is connected to the first drain terminal 213 and the second induction coil 232 is connected to the first source terminal 212; a second transformer inductor 24, wherein the inductor is a coupling inductor in the cross-coupled LC-tank voltage-controlled oscillating circuit 20, and the second transformer inductor 24 includes a third induction coil 241 and a fourth induction coil 242; and a capacitor set 25.

Moreover the third induction coil 241 is connected to the second drain terminal 223, the fourth induction coil 242 is connected to the second source terminal 222; and the first induction coil 231 and the third induction coil 241 are connected to a working voltage supply 26; the second induction coil 232 and the fourth induction coil 242 are connected to ground.

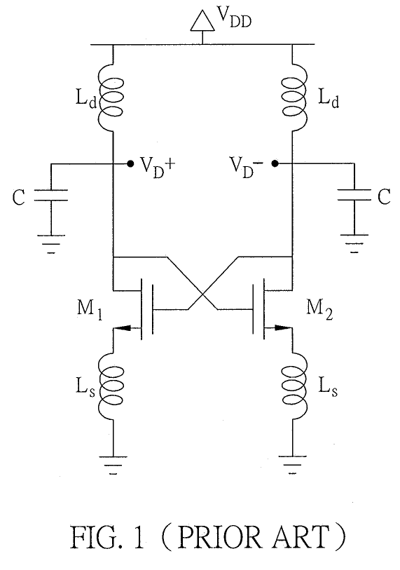

As shown in FIGS. 1 and 2, compare the conventional voltage-controlled oscillator with the voltage-controlled oscillator as disclosed in the present invention, it can be obtained that the present invention adopts the planar transformer technology, allowing the first induction coil 231 and the second induction coil 232 of the first transformer inductor 23, and the third induction coil 241 and the fourth induction coil 242 of the second transformer inductor 24 to replace the four inductors of the conventional voltage-controlled oscillator. In other words, the four conventional inductors can be realized by two sets of transformer inductor using the planar transformer technology, thereby reducing the inductor area of the voltage-controlled oscillator significantly.

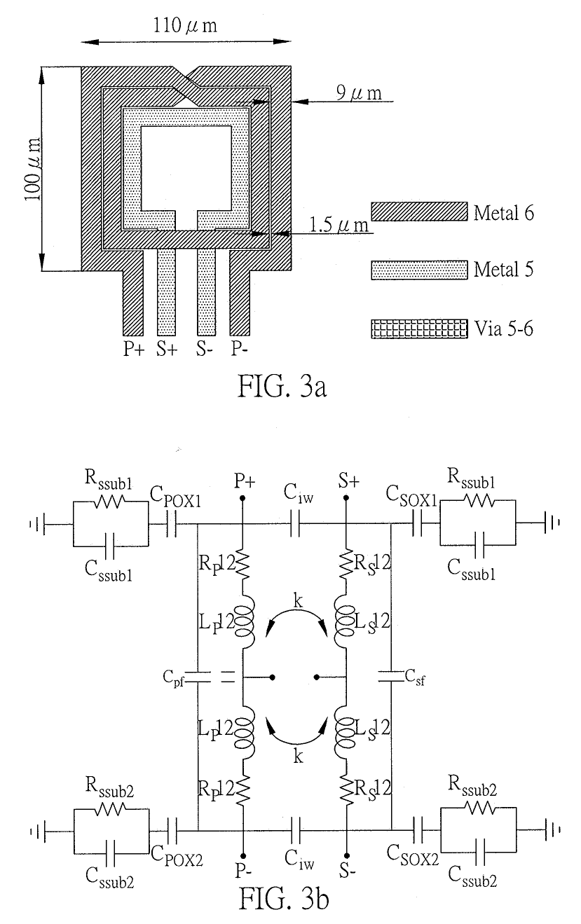

Regarding the planar transformer technique replacing the conventional inductors in the voltage-controlled oscillator, FIG. 3a illustrates the planar transformers used in the voltage-controlled oscillator. As shown in the diagram, P is an induction coil, and S is another induction coil. Further, induction coil P and induction coil S form a coupling structure, which can greatly reduce the inductor area of the transistor voltage-controlled oscillator. Also as reducing the inductor area lowers the parasitic capacitance present between the inductor and the silicon substrate, the power consumption can be significantly lowered, leading to an increase in the Q-factor of the inductor. Referring to FIG. 3b for further information as it displays an equivalent circuit diagram of a planar transformer.

### Second Embodiment

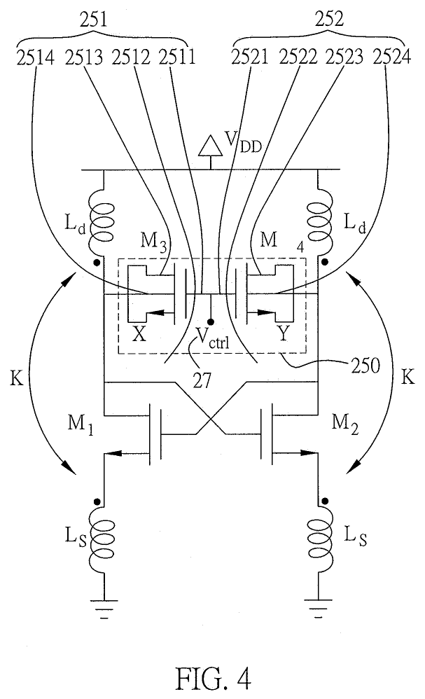

Referring to FIG. 4, a circuit diagram of a transistor voltage-controlled oscillator in the second embodiment is illustrated. The difference between the second embodiment and the first embodiment is that an NMOS transistor variable capacitor set 250 replaces the capacitor set 25; the NMOS transistor variable capacitor set 250 includes a third transistor 251 and a fourth transistor 252.

Also, the third transistor 251 includes a third gate terminal 2511, a third source terminal 2512, a third drain terminal 2513 and a third substrate 2514, and the fourth transistor 252 includes a fourth gate terminal 2521, a fourth source terminal 2522, a fourth drain terminal 2523 and a fourth substrate 2524. The third source terminal 2512 is coupled to the third drain terminal 2513, the fourth source terminal 2522 is coupled to the fourth drain terminal 2523. Furthermore the third substrate 2514 is coupled to the first drain terminal 213, and the fourth substrate 2524 is coupled to the second drain terminal 223. In addition, the third gate terminal 2511 and the fourth gate terminal 2521 are coupled to a control voltage source 27. The control voltage source 27 serves the purpose of adjusting the capacitance of the NMOS transistor variable capacitor set 250.

### Third Embodiment

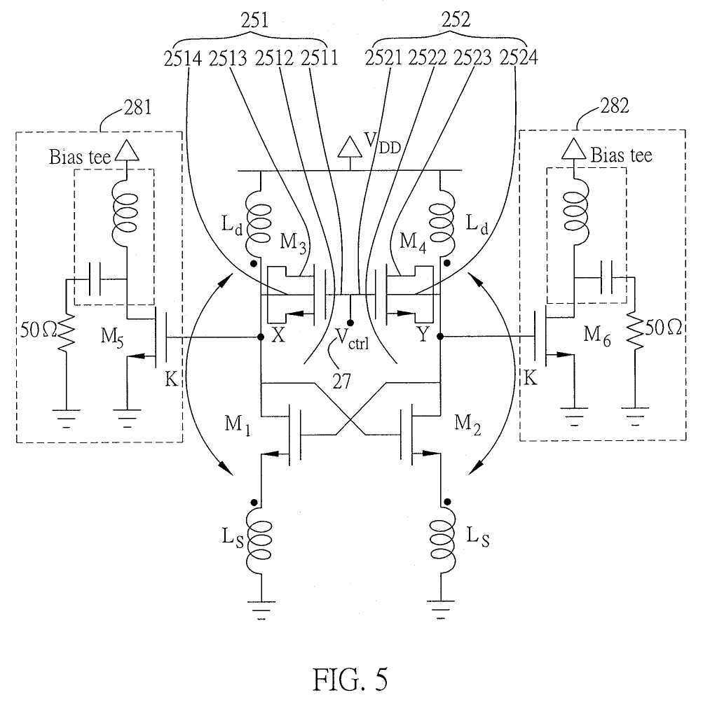

Referring to FIG. 5, a circuit diagram of a transistor voltage-controlled oscillator of the present invention in the third embodiment is illustrated. The difference between the third embodiment and the second embodiment is that the transistor voltage-controlled oscillator in the third embodiment includes two extra sets of output buffer amplifiers 281 and 282 which serve the purpose of stabilizing the output signals of the transistor voltage-controlled oscillator and increasing the output signal swing.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. A transistor voltage-controlled oscillator, at least comprising:
a cross-coupled LC-tank transistor voltage-controlled oscillating circuit comprising a first transistor with a first gate terminal, a first source terminal and a first drain terminal and a second transistor with a second gate terminal, a second source terminal and a second drain terminal;
a first transformer inductor used as a coupling inductor in the cross-coupled LC-tank voltage-controlled oscillating circuit and comprising a first induction coil and a second induction coil, wherein the first induction coil is connected to the first drain terminal and the second induction coil is connected to the first source terminal; and
a second transformer inductor used as a coupling inductor in the cross-coupled LC-tank voltage-controlled oscillating circuit and comprising a third induction coil and a fourth induction coil, wherein the third induction coil is connected to the second drain terminal and the fourth induction coil is connected to the second source terminal.

2. The transistor voltage-controlled oscillator of claim 1, wherein the structures of the first transformer and the second transformer are planar transformer structures.

3. The transistor voltage-controlled oscillator of claim 1, wherein the first gate terminal is connected to the second drain terminal, and the second gate terminal is connected to the first drain terminal.

4. The transistor voltage-controlled oscillator of claim 1, wherein the first induction coil and the third induction coil are connected to a working voltage supply.

5. The transistor voltage-controlled oscillator of claim 1, wherein the second induction coil and the fourth induction coil are connected to the ground.

6. The transistor voltage-controlled oscillator of claim 1, wherein the cross-coupled LC-tank transistor voltage-controlled oscillating circuit further comprises a capacitor set.

7. The transistor voltage-controlled oscillator of claim 6, wherein the capacitor set is an NMOS transistor variable capacitor set comprising a third transistor and a fourth transistor.

8. The transistor voltage-controlled oscillator of claim 7, wherein the third transistor comprises a third gate terminal, a third source terminal, a third drain terminal and a third substrate, and the fourth transistor comprises a fourth gate terminal, a fourth source terminal, a fourth drain terminal and a fourth substrate.

9. The transistor voltage-controlled oscillator of claim 8, wherein the third source terminal is connected to the third drain terminal, the fourth source terminal is connected to the fourth drain terminal, the third substrate is connected to the first drain terminal, and the fourth substrate is connected to the second drain terminal.

10. The transistor voltage-controlled oscillator of claim 8, wherein the third gate terminal and the fourth gate terminal are connected to a control voltage source used for adjusting the capacitance of the NMOS transistor variable capacitor set.

11. The transistor voltage-controlled oscillator of claim 1 further comprising two sets of output buffer amplifiers for stabilizing output signals of the transistor voltage-controlled oscillator and increasing the output signal swing.
